(19) United States
(12) Patent Application Publication
(10) Pub. No.: US 2018/0017608 A1
(43) Pub. Date: Jan. 18, 2018

(54) ELECTRICAL IN-SYSTEM PROCESS CONTROL TESTER

(71) Applicant: FORD MOTOR COMPANY OF CANADA, LIMITED, Oakville (CA)

(72) Inventors: Kishan NITHYANANDAN, Mississauga (CA); Jimi TJONG, Kingsville (CA); Bede ALOYSIUS, Maple (CA); Usman WASEEM, Oakville (CA)

(21) Appl. No.: 15/207,753

(22) Filed: Jul. 12, 2016

(51) Int. Cl. G01R 31/00; H04B 17/00; G01R 31/08; H04W 24/06; G01R 31/04

(52) U.S. Cl. CPC G01R 31/007; H04W 24/06; G01R 31/041; G01R 31/088; H04B 17/0085

(57) ABSTRACT

A tester apparatus includes a wireless network interface and a device-under-test interface; and a processor, in communication with the network interface and the device-under-test interface. The processor is programmed to identify parameters of an electrical test from a remote server via the wireless network interface, perform the electrical test to an assembly electrically connected to the device-under-test interface, and report results of the electrical test to the remote server via the wireless network interface. A server may be in wireless communication with the tester apparatus and a station of an assembly line via a network access point. The server is programmed to send parameters of an electrical test of an assembly to the tester apparatus; receive test results from the tester apparatus, the test results indicating a wiring connection fault; and graphically display a fault indication overlaid on an image of the assembly to indicate location of the wiring fault.

### TECHNICAL FIELD

Aspects of the disclosure generally relate to an in-system process control tester for electrical vehicle systems.

### BACKGROUND

Currently automakers are increasing their offerings of technologies in vehicles for safety, performance, entertainment, and connectives. This has increased the number of electrical connections in vehicles an assembly plant has to complete. A vehicle may have hundreds of connections made by line operators during vehicle assembly. This is a very operator-dependent process. Current validation processes for electrical connections can depend on complete assembly testing or final vehicle testing. These tests are at the end of the assembly process. Detection of any error in electrical connection at that end of the line results in first-time-through (FTT) loss, increased mean-time-to-repair (MTR) due to disassembly requirements to reach the connection and also the collateral damage to interior and exterior components in the vehicle.

### SUMMARY

In one or more illustrative embodiments, a system includes a wireless network interface; a device-under-test interface; and a processor, in communication with the network interface and the device-under-test interface, programmed to identify parameters of a test from a remote server via the wireless network interface, perform the test to an assembly electrically connected to the device-under-test interface, and report results of the test to the remote server via the wireless network interface.

In one or more illustrative embodiments, a system includes a server, in wireless communication with a tester apparatus and a station of an assembly line via a network access point, programmed to send parameters of an electrical test of an assembly to the tester apparatus; receive test results from the tester apparatus, the test results indicating a wiring connection fault; and graphically display a fault indication overlaid on an image of the assembly to indicate the location of the wiring connection fault.

In one or more illustrative embodiments, a method includes identifying parameters of an electrical test from a remote server via a network interface; performing the electrical test by a tester apparatus to an assembly electrically connected to a device-under-test interface; and reporting results of the electrical test to a remote server via the network interface.

### BRIEF DESCRIPTION OF THE DRAWINGS

FIG. 1 illustrates a block diagram of an example assembly line for a vehicle;

FIG. 2 illustrates a block diagram of an example wireless electronic tester;

FIG. 3 illustrates an example user interface use of the wireless electronic tester;

FIG. 4 illustrates an example process for using the wireless electronic tester to test a device under test;

FIG. 5 illustrates an example process of the server of the assembly line receiving test data from the wireless electronic tester; and

FIG. 6 illustrates an example user interface displaying data received from the wireless electronic tester.

### DETAILED DESCRIPTION

As required, detailed embodiments of the present invention are disclosed herein; however, it is to be understood that the disclosed embodiments are merely examples of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

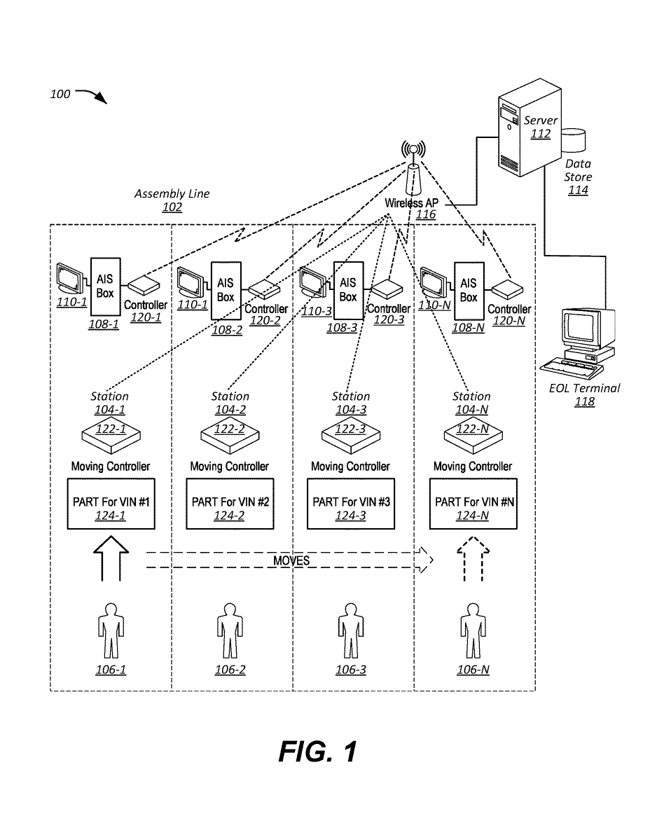

FIG. 1 illustrates a block diagram 100 of an example assembly line 102. The assembly line 102 includes multiple work stations 104-1 through 104-N (collectively 104) at which line operators 106-1 thorough 106-N (collectively 106) make electrical connections to assemblies as part of an overall build process. The stations 104 include an assembly information system (AIS) boxes 108-1 through 108-B (collectively 108) providing output to corresponding terminals 110-1 through 110-N (collectively 110) to inform the line operator 106 what operations to perform on the assembly line 102. The assembly line 102 also includes a main server 112 configured to maintain build and station 104 mapping information in a data store 114. (The main server 112 also maintains tester 202 mapping information as discussed below.) The main server 112 provides information to corresponding transceivers 120 connected to the AIS boxes 108 using a wireless access point 116, thereby instructing the line operators 106 of the electrical connection confirmation at to be performed at each station 104. An end of line (EOL) terminal 118 may be in communication with the server 112 to provide visualization of the overall build process.

The stations 104 may be organized in a workflow, e.g., from station 104-1 to station 104-2, then to station 104-3, and so on through to final station 104-N. Each assembly being assembled may accordingly traverse the workflow from one station 104 to the next. In an example, the assemblies may be moved along a conveyor or belt from station 104 to station 104. To track the assemblies, the assemblies (or carriers of the assemblies) may be associated with transceivers 122-1 through 122-N (collectively 122) that travel with the assemblies. These assemblies may be in communication with the wireless access point 116 to allow the server 112 to track the locations of the assemblies through the assembly line 102. For instance, the transceivers 120 may indicate the VIN of the vehicle for which the assembly is being assembled. This indication of VIN may also allow for the line 102 to identify the parts 124-1 through 124-N at the stations 104 to be attached to the assemblies during the build.

Each station 104 may have a capability of 99%, meaning that each operator 106 will complete a given task correctly 99% of the time. The throughput of the line 102 may be a lower percentage, such as 95%. When this is expanded into an assembly plant with hundreds of work stations 104, roll-throughput significantly drops. Every operation is attempted to be as close to 100% as possible to avoid faults, because if there is a fault with a vehicle, then the vehicle may require teardown. In turn, teardown may affect throughput or may cause space issues for where the fault vehicle can be placed for repair. Hence, testing at the end of the line 102 at best provides for error detection but not error prevention.

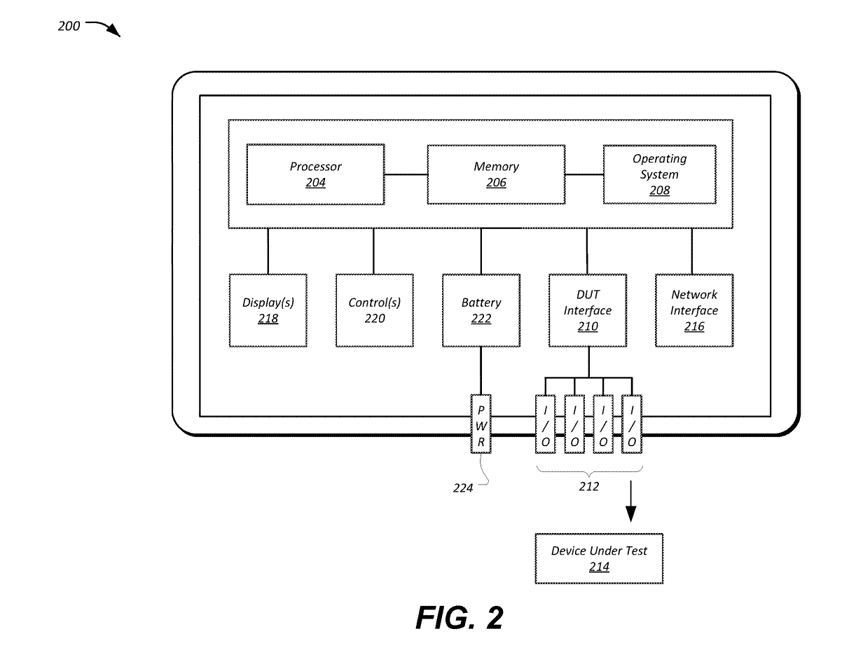

FIG. 2 illustrates a block diagram 200 of an example wireless electrical tester 202. The wireless electrical tester 202 may be used as an inspection apparatus to validate a group of connections of an assembly, to ensure that the assembly is correctly wired prior to leaving that station 104.

The tester 202 may include a main board having at least one processor 204, a memory 206, and an operating system 208 installed thereon. The main board may also be connected to one or more displays 218 to visually or otherwise provide information to a user, and to one or more controls 220 used to configure the operation of the tester 202. The tester 202 may also include a battery 132 to power the tester 202. The main board may also be connected to a device-under-test (DUT) interface 210 to provide for the connection of the tester 202 to assemblies (e.g., devices under test 214). Using the tester 202, the line operators 106 can verify that the electrical wiring of the device under test 214 is properly completed. The tester 202 may take many different forms and include multiple and/or alternate components and facilities. While an example tester 202 is shown in FIG. 2, the example components as illustrated are not intended to be limiting. Indeed, additional or alternative components and/or implementations may be used.

The at least one processor 204 may be configured to perform instructions, commands, and other routines in support of the processes described herein. For instance, the processor 204 may be configured to execute instructions of Linux or another embedded operating system 208. Such instructions of the operating system 208 and other data may be maintained in a non-volatile manner using a variety of types of computer-readable storage medium. A computer-readable medium (also referred to as a processor-readable medium or storage) includes any non-transitory medium (e.g., a tangible medium) that participates in providing instructions or other data that may be read by the processor 204. Computer-executable instructions may be compiled or interpreted from computer programs created using a variety of programming languages and/or technologies, including, without limitation, and either alone or in combination, Java, C, C++, C#, Objective C, Fortran, Pascal, Java, Java Script, Python, Perl, and PL/SQL.

The DUT interface 210 may be configured to provide input and output functionality to the tester 202. In an example, the DUT interface 210 may include one or more I/O ports 212 to which external devices to be tested by the tester 202 may be connected. Using the facilities of the DUT interface 210, the tester 202 may be used to verify the electrical properties of the device under test 214. As some possibilities, the DUT interface 210 may support the testing of electrical properties such as continuity, resistance, impedance, and capacitance. The operating system 208 may be configured to facilitate continuity or other electrical testing of the device under test 214 connected to one or more I/O ports 212 of the DUT interface 210.

To facilitate connection to the device under test 214, the I/O ports 212 may be connected to one or more probes that the operator 106 may use to connect to electrical connections of the device under test 214. As another possibility, a cable with a MOLEX or other connector that fits to the device under test 214 may be connected from the I/O ports 212 of the DUT interface 210, to allow the operator 106 to engage the connector to the device under test 214. The device under test 214 may be, in an example, a door panel wiring harness of a vehicle, but other examples are possible.

The network interface 216 may include a wireless modem to facilitate connection of the tester 202 to a communications network. For instance, the tester 202 may use the network interface 216 to communicate with the access point 116 of the server 112. The operating system 208 may accordingly use the network interface 216 to communicate test results determined from the assembly connected to the DUT interface 210 to the server 112.

The display 218 may include one or more devices configured to provide information to a user of the tester 202. In some examples, the display 218 may be a touchscreen configured to receive input as well as display information, while in other cases the display 218 may simply provide information. In some cases, the display 218 may include one or more lights or indicators with dedicated functions, while in other cases the display 218 may include a general-purpose display device, such as a liquid crystal display (LCD) panel, a light-emitting diode (LED) display, or an organic LED (OLED) display.

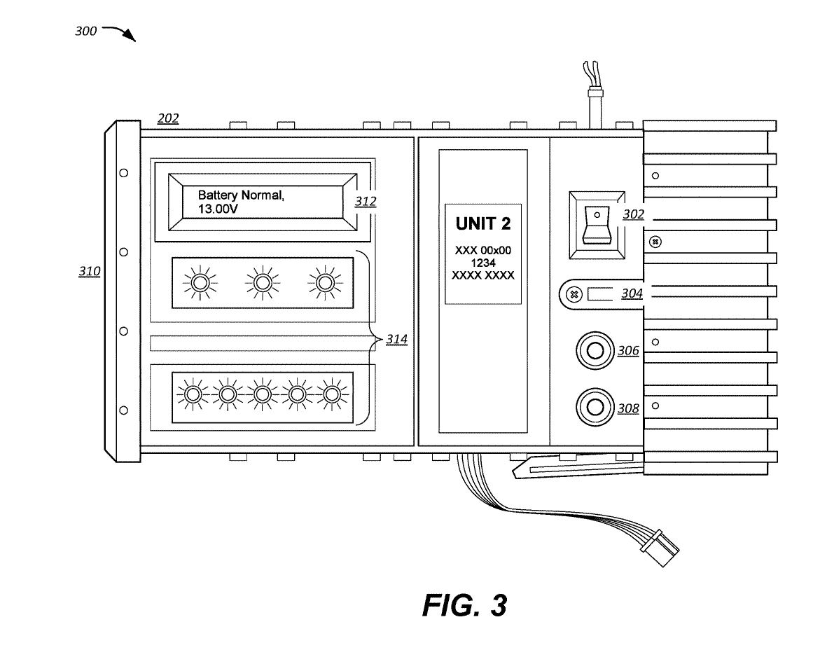

The controls 220 may include one or more switches, buttons, or other devices that may be used by the operator 106 to configure the operation of the tester 202. Example displays 218 and controls 220 are discussed in detail below with respect to FIG. 3.

The battery 222 may include one or more cells, capacitors, or other devices configured to store electrical energy for use in powering the tester 202. The battery 222 may be connected to the main board to provide power to the processor 204 and display(s) 218. The battery 222 may also be connected to a power input 224 of the tester 202 to allow the battery 222 to receive power from an external source for charging the battery 222 and/or for operating the tester 202. The external source may be, as some possibilities, an accessory power port (e.g., 6, 12, or 24 Volts direct current), a power adapter configured to plug into a home wall outlet (e.g., 120 Volts or 240 Volts alternating current, etc.), or an external renewable energy source.

FIG. 3 illustrates an example 300 of a user interface of the wireless electronic tester 202. The user interface may include one or more displays 218 and controls 220 mounted to the tester 202 and manipulated by the line operators 106 when verifying electrical connections of the device under test 214. In the illustrated example, the controls 220 include a power switch 302, a manual/automatic mode switch 304, a Wi-Fi connect switch 306, a test start switch 308, and a VIN sync switch 310. The displays 218 in the illustrated example include a screen 312 and a set of test input status lights 314. It should be noted that the illustrated user interface and layout is only an example, and more, fewer, and different displays 218 and controls 220 may be used.

The power switch 302 may be selected to control whether power is applied to the tester 202, processor 204, and other electronics. When the power switch 302 is set to on, the tester 202 may be powered, while when the power switch 302 is set to off, the tester 202 may be turned off to conserve battery 132 power.

The manual/automatic mode switch 304 may be used by the operator 106 to select between an automatic mode of operation of the tester 202, in which the tester 202 performs a predefined set of tests to the device under test 214, and a manual mode of operation, in which the operator 106 manually performs one or more tests to the device under test 214.

The Wi-Fi connect switch 306 may be selected to trigger the tester 202 to attempt connection to a communication network using the network interface 216. For instance, responsive to selection of the Wi-Fi connect switch 306, the processor 204 may direct the network interface 216 to connect to the server 112.

The test start switch 308 may be selected to trigger the tester 202 to perform one or more tests to the device under test 214 connected to the tester 202. For instance, responsive to selection of the test start switch 308, the processor 204 may direct the DUT interface 210 to validate one or more electrical properties of a device under test 214 connected to the tester 202. These properties may include, for example, continuity, resistance, impedance, and/or capacitance between one or more connections of the device under test 214 and the I/O ports 212 of the tester 202.

The tester 202 may operate as a continuity tester and may perform a continuity test using the continuity tester to determine, for example, whether an electrical path can be established between two points. For instance, the tester 202 may apply a square wave at a fixed frequency with a calibrated source resistance to connections of the device under test 214. The result of the continuity test may be, for example, pass if continuity is established for connections that should be connected and fail if continuity is not established for connections that should be connected. Or, for connections that should not be connected, the result of the continuity test may be pass if continuity is not established and fail if continuity is established. Other types of test may be performed as well. For instance an ohmmeter of the tester 202 may be used to confirm that a resistance value between connections is within a predefined range, or is at, below or above a predefined value. If so, the test may pass, if not the test may fail. The specific locations to test and success criteria may be referred to as test parameters, and the specific test parameters to be performed may be received wirelessly from the server 112.

The VIN sync switch 310 may be selected to trigger the tester 202 to sync up to the VIN of the assembly of the station 104 in which the tester 202 is currently testing. For instance, responsive to selection of the Wi-Fi connect switch 306, the processor 204 may direct the network interface 216 to request that the server 112 identify to the tester 202 the VIN or other identifier of the assembly presently located at the station 104 at which the tester 202 is associated. Knowing the VIN or other identifier of the assembly may be useful for the tester 202 in providing the test results to the server 112 in association with the identifier of the assembly being tested. This may accordingly allow the server 112 to track the test results for the assemblies according to the vehicle in which the assemblies are to be incorporated.

The screen 312 may display information indicative of the status of tests and/or of the tester 202 device itself. In an example, the screen 312 may display an indication of the charge level of the battery 132 of the tester 202, or whether the tester 202 is plugged into an external power source. The test input status lights 314 may be used to display aspects of the test to be performed or being performed by the tester 202.

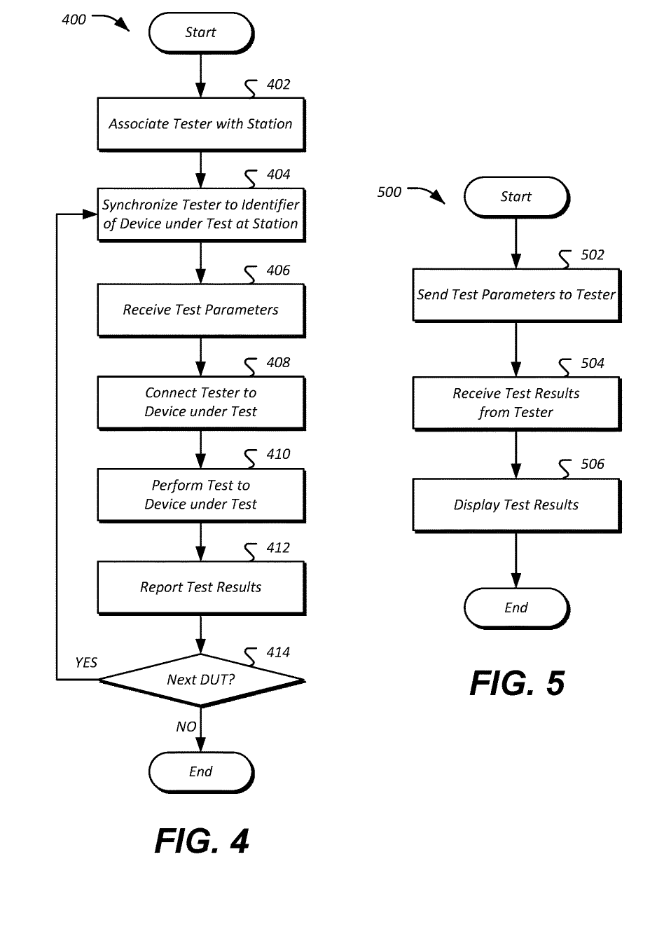

FIG. 4 illustrates an example process 400 for using the wireless electronic tester 202 to test a device under test 214. In an example, the process 400 may be performed by the tester 202 in the assembly line 102 environment described above with respect to FIG. 1.

At operation 402, the tester 202 is associated with a station 104 of the assembly line 102. In an example, the tester 202 may wirelessly provide to the server 112 a unique identifier of the tester 202 device and a station 104 location of the tester 202 which may be stored by the server 112. The station 104 location may be entered to the tester 202 by the line operator 106 of the tester 202, as an example.

At operation 404, the tester 202 synchronizes with the VIN or other identifier of the assembly at the station 104. In an example, the tester 202 may receive input to the VIN sync switch 310 to trigger the tester 202 to sync up to the VIN of the assembly of the station 104 in which the tester 202 is currently testing. In response, the tester 202 may wirelessly access the server 112 to receive the VIN of the assembly. In another example, the tester 202 may wirelessly access the AIS box 108 corresponding to the station 104 in which the tester 202 is associated to receive the VIN of the assembly.

At operation 406, the tester 202 receives test parameters from the server 112. In an example, the tester 202 may further receive additional information regarding the assembly in response to the synchronization at operation 404, such as information indicative of the build configuration of the assembly or tests to be performed to the assembly. In another example, the tester 202 may separately request build configuration or test information from the server 112 or from the AIS box 108 corresponding to the station 104 in which the tester 202 is associated. Based on the test information or build information, the tester 202 may determine what tests should be performed against the assembly. For instance, an assembly that includes an up-level audio system with additional speakers connected to a wiring harness may have additional electrical connections to be tested, as compared to a basic audio system in which the wiring harness lacks connections where the optional speakers are not included.

At operation 408, the tester 202 connects to the device under test 214. In an example, the device under test 214 may be electrically attached to the DUT interface 210 of the tester 202. The connection may be, for example, performed responsive to a connector that fits to the device under test 214 being connected to the assembly and also to the I/O ports 212 of the DUT interface 210. In some examples, the tester 202 may indicate in one or more displays 218 of the tester 202 when the apparatus is electrically connected to the tester 202.

At operation 410, the tester 202 performs the test to the device under test 214. In an example, the tester 202 may perform tests to the device under test 214 according to the received test parameters.

At operation 412, the tester 202 reports the test results. In an example, the tester 202 may wirelessly send the test results to the server 112 and/or to the AIS box 108 corresponding to the station 104 in which the tester 202 is associated. Responsive to receipt of the test results, the server 112 and/or AIS 108 may identify that the operations to be performed to the assembly at the station 104 have been completed successfully or unsuccessfully.

At operation 414, the tester 202 determines whether to proceed to the next device under test 214. For instance, the tester 202 may determine that the VIN sync switch 310 has again been selected. As another example, the tester 202 may be wirelessly informed via the server 112 and/or AIS box 108 that a new assembly has moved to the station 104. If so, control passes to operation 404. Otherwise, the process 400 ends.

FIG. 5 illustrates an example process 500 of the server 112 of the assembly line receiving test data from the wireless electronic tester 202. In an example, the process 500 may be performed by the server 112 in the assembly line 102 environment described above with respect to FIG. 1.

At operation 502, the server 112 sends the test parameters to the tester 202. In an example, the server 112 may send the test parameters to the tester 202 responsive to a request from the tester 202 as discussed above with respect to operation 406.

At operation 504, the server 112 receives the test results from the tester 202. In an example, the server 112 may receive the test results from the tester 202 as discussed above with respect to operation 412. The server 112 may accordingly collate the test results with the VIN of the vehicle into which the assembly is to be included.

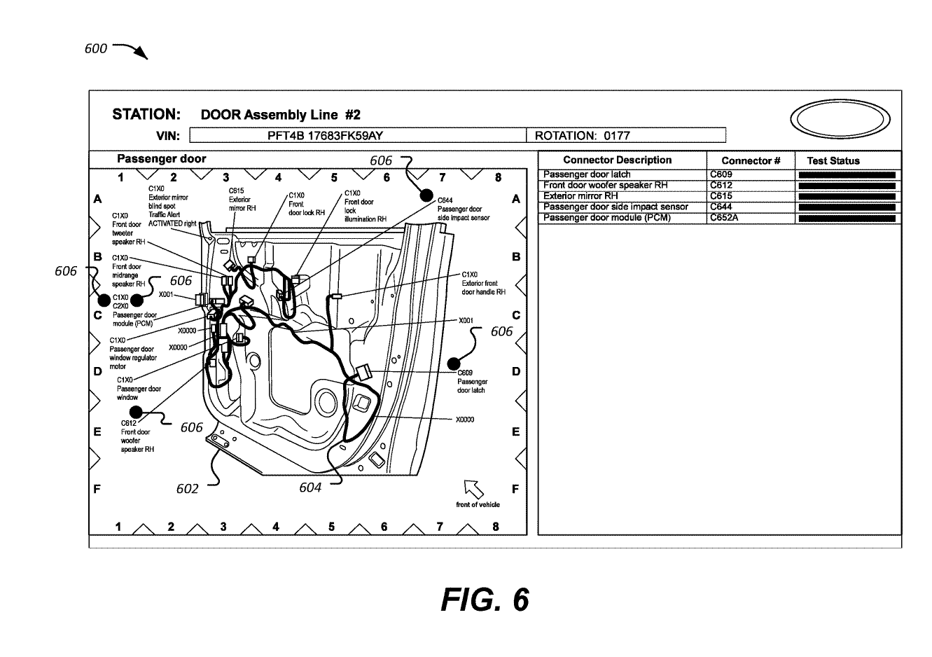

At operation 506, the server 112 displays the test results. In an example, the server 112 may display the results for one or more vehicles via the EOL terminal 118, discussed in detail with respect to FIG. 6 below. After operation 506, the process 500 ends.

FIG. 6 illustrates an example user interface 600 displaying data received from the wireless electronic tester 202. In an example, the user interface 600 may be displayed by the EOL terminal 118 in communication with the server 112 of the assembly line 102. As illustrated, the user interface 600 includes a graphical assembly representation 602 of the assembly. Overlaid on the representation 602 is an electrical connection 604 illustration indicating placement of the wiring within the assembly. Moreover, based on the test results received from the tester 202, electrical fault indications 606 may be displayed on the representation 602 to indicate what electrical connection 604 points test as having been assembled incorrectly. For instance, electrical connections deemed as failed in the test results for the illustrated assembly may be shown with the electrical fault indication 606. Accordingly, based on the information, an operator of the EOL terminal 118 may visually receive information indicative of electrical connection issued in the assembly, and may determine to perform operations such as to stop the line or to queue up the vehicle in which the faulty assembly is included for later repair.

In general, computing systems and/or devices, such as the AIS box 108, server 112, and tester 202, may employ any of a number of computer operating systems, including, but by no means limited to, versions and/or varieties of the Microsoft Windows® operating system, the Unix operating system (e.g., the Solaris® operating system distributed by Oracle Corporation of Redwood Shores, Calif.), the AIX UNIX operating system distributed by International Business Machines of Armonk, N.Y., the Linux operating system, the Mac OS X and iOS operating systems distributed by Apple Inc. of Cupertino, Calif., the BlackBerry OS distributed by Research In Motion of Waterloo, Canada, and the Android operating system developed by the Open Handset Alliance.

Computing devices, such as the AIS box 108, server 112, and tester 202, generally include computer-executable instructions that may be executable by one or more processors of the computing devices. Computer-executable instructions, such as those of the web control application 138, may be compiled or interpreted from computer programs created using a variety of programming languages and/or technologies, including, without limitation, and either alone or in combination, Java™, C, C++, Visual Basic, Java Script, Perl, etc. In general, a processor or microprocessor receives instructions, e.g., from a memory, a computer-readable medium, etc., and executes the instructions, thereby performing one or more processes, including one or more of the processes described herein. Such instructions and other data may be stored and transmitted using a variety of computer-readable media.

A computer-readable medium (also referred to as a processor-readable medium) includes any non-transitory (e.g., tangible) medium that participates in providing data (e.g., instructions) that may be read by a computer (e.g., by a processor of a computing device). Such a medium may take many forms, including, but not limited to, non-volatile media and volatile media. Non-volatile media may include, for example, optical or magnetic disks and other persistent memory. Volatile media may include, for example, dynamic random access memory (DRAM), which typically constitutes a main memory. Such instructions may be transmitted by one or more transmission media, including coaxial cables, copper wire, and fiber optics, including the wires that comprise a system bus coupled to a processor of a computer. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, an EPROM, a FLASH-EEPROM, any other memory chip or cartridge, or any other medium from which a computer can read.

In some examples, system elements may be implemented as computer-readable instructions (e.g., software) on one or more computing devices (e.g., servers, personal computers, etc.), stored on computer readable media associated therewith (e.g., disks, memories, etc.). A computer program product may comprise such instructions stored on computer readable media for carrying out the functions described herein. Some or all of the operations disclosed herein as being performed by the AIS box 108, server 112, and tester 202 may be such computer program products. In some examples, these computer program products may be provided as software that when executed by one or more processors provides the operations described herein. Alternatively, the computer program products may be provided as hardware or firmware, or combinations of software, hardware, and/or firmware.

While example embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

What is claimed is:

1. A system comprising:
a wireless network interface;
a device-under-test interface; and
a processor, in communication with the network interface and the device-under-test interface, programmed to
identify parameters of an electrical test from a remote server via the wireless network interface,
perform the electrical test to an assembly electrically connected to the device-under-test interface, and
report results of the electrical test to the remote server via the wireless network interface.

2. The system of claim 1, wherein the parameters of the electrical test include data indicative of connections of the assembly to be tested.

3. The system of claim 1, wherein the processor is further programmed to:
synchronize with the remote server to determine a unique identifier of a vehicle in which the assembly is to be included; and
identify the parameters of the electrical test according to a build configuration associated with the unique identifier of the vehicle.

4. The system of claim 3, wherein the unique identifier is a vehicle identification number (VIN) of the vehicle.

5. The system of claim 1, wherein the electrical test includes a continuity test between connections of the assembly to the device-under-test interface.

6. The system of claim 1, wherein the electrical test includes a resistance test between connections of the assembly to the device-under-test interface.

7. The system of claim 1, wherein the electrical test includes a capacitance test between connections of the assembly to the device-under-test interface.

8. The system of claim 1, wherein the network interface is configured to access the remote server by communicating with a Wi-Fi access point in communication with the server.

9. A system comprising:
a server, in wireless communication with a tester apparatus and a station of an assembly line via a network access point, programmed to:
send parameters of an electrical test of an assembly to the tester apparatus;
receive test results from the tester apparatus, the test results indicating a wiring connection fault; and
graphically display a fault indication overlaid on an image of the assembly to indicate location of the wiring connection fault.

10. The system of claim 9, wherein the server is further programmed to:
receive, from the tester apparatus, a request to synchronize the tester apparatus to a unique identifier of a vehicle in which the assembly is to be included; and
identify the parameters of the electrical test according to a build configuration associated with the unique identifier of the vehicle.

11. The system of claim 9, wherein the server is further programmed to associate the tester apparatus with the station of the assembly line.

12. The system of claim 9, wherein the electrical test includes one or more of: a continuity test between connections of the assembly; a resistance test between connections of the assembly; or a capacitance test between connections of the assembly.

13. A method comprising:
identifying parameters of an electrical test from a remote server via a network interface;
performing the electrical test by a tester apparatus to an assembly electrically connected to a device-under-test interface; and
reporting results of the electrical test to a remote server via the network interface.

14. The method of claim 13, wherein the results indicate a wiring fault, and further comprising graphically displaying a fault indication overlaid on an image of the assembly to indicate location of the wiring fault.

15. The method of claim 13, further comprising
synchronizing the tester apparatus with the remote server to determine a unique identifier of a vehicle in which the assembly is to be included; and
identifying the parameters of the electrical test according to a build configuration associated with the unique identifier of the vehicle.

16. The method of claim 13, further comprising performing the electrical test by one or more of: performing a continuity test between connections of the assembly; performing a resistance test between connections of the assembly; or performing a capacitance test between connections of the assembly to the device-under-test interface.
